(19) United States
(12) Patent Application Publication
(10) Pub. No.: US 2025/0143186 A1
(43) Pub. Date: May 1, 2025

(54) LIQUID EJECTION HEAD AND PIEZOELECTRIC ACTUATOR

(71) Applicant: CANON KABUSHIKI KAISHA, Tokyo (JP)

(72) Inventors: AKIHISA IIO, Kanagawa (JP); REI KURASHIMA, Kanagawa (JP)

(21) Appl. No.: 18/931,584

(22) Filed: Oct. 30, 2024

(30) Foreign Application Priority Data
Nov. 1, 2023 (JP) 2023-187840

(51) Int. Cl. H10N 30/88; B41J 2/14; H10N 30/87

(52) U.S. Cl. CPC H10N 30/883; B41J 2/14233; H10N 30/871; H10N 30/872; B41J 2002/14241

(57) ABSTRACT

A liquid ejection head is provided that can suppress peeling from end portions of a piezoelectric layer and an electrode layer and peeling from wiring above a contact portion while ensuring a required amount of displacement of a piezoelectric element. To this end, a protective film is formed so as to cover a partial region including an end portion of a first electrode below a piezoelectric film, a partial region including an end portion of a second electrode above the piezoelectric film, and a second layer wiring above a contact portion, across a center of the piezoelectric film.

### BACKGROUND

### Field

The present disclosure relates to a liquid ejection head having a piezoelectric element.

### Description of the Related Art

With the development of MEMS (Micro Electro Mechanical Systems) technology, thin-film piezoelectric elements based on a semiconductor process have recently been proposed.

Japanese Patent Laid-Open No. 2021-024141 discloses a configuration in which a peripheral portion of an upper electrode on its upper surface, the entire side surfaces of the upper electrode and a piezoelectric film, and a peripheral portion of a lower electrode are covered with an insulating film made of, for example, silicon dioxide (SiO₂), while a contact portion between the lower electrode and a wiring is not covered with the insulating film.

Japanese Patent Laid-Open No. 2016-058716 also discloses a configuration in which a peripheral portion of an upper electrode on its upper surface, the entire side surfaces of the upper electrode and a piezoelectric film, a lower electrode, and a contact portion are covered with a protective film.

However, in the configuration disclosed in Japanese Patent Laid-Open No. 2021-024141, peeling of an electrode layer and the wiring or peeling from an end portion of the piezoelectric film may occur in the contact portion not covered with the insulating film, leading to a possibility that sufficient fastness may not be obtained in the piezoelectric element.

Moreover, in the configuration disclosed in Japanese Patent Laid-Open No. 2016-058716, an electrode layer of a piezoelectric body is provided beyond the range of a pressure chamber, and a plurality of protective films are laminated beyond the range of the pressure chamber. Such a configuration in which a plurality of protective films are laminated beyond the range of the pressure chamber, as in Japanese Patent Laid-Open No. 2016-058716, the film thickness from the outside to the inside of the pressure chamber increases to restrain the end portion of the piezoelectric element. This poses a problem of difficulty in obtaining necessary displacement of the piezoelectric element.

### SUMMARY

Therefore, the present disclosure provides a liquid ejection head including a piezoelectric element with high fastness while ensuring a required amount of displacement.

Therefore, a liquid ejection head according to the present disclosure includes: a laminate of a substrate having a pressure chamber formed therein that is communicated with an ejection port for ejecting a liquid, a vibration plate that vibrates to generate pressure in the liquid in the pressure chamber, a piezoelectric film that vibrates the vibration plate by applying a voltage, a first electrode provided on one surface of the piezoelectric film between the piezoelectric film and the vibration plate, and a second electrode provided on the other surface of the piezoelectric film; a first wiring connected to the first electrode by a first contact portion; a second wiring connected to the second electrode by a second contact portion; and a protective film having at least a first portion covering a partial region including an end portion of the first electrode, the first contact portion, and the first wiring, and a second portion covering a partial region including an end portion of the second electrode, the second contact portion, and the second wiring, at one end side and the other end side of the piezoelectric film in a longitudinal direction of the piezoelectric film within a range overlapping with the pressure chamber as seen from a direction perpendicular to the substrate.

Further features of the present disclosure will become apparent from the following description of exemplary embodiments with reference to the accompanying drawings.

### BRIEF DESCRIPTION OF THE DRAWINGS

FIGS. 1A and 1B are diagrams showing an element substrate;

FIG. 2 is a top view of a channel substrate seen from the piezoelectric film side in a one-chip element substrate;

FIG. 3 is a schematic cross-sectional view taken along line III-III in FIG. 2;

FIG. 4 is a top view showing a vicinity of III-III in FIG. 2;

FIG. 5 is a cross-sectional view taken along line V-V in FIG. 4;

FIGS. 6A to 6E are diagrams showing a manufacturing process of a piezoelectric element in sequence;

FIG. 7 is a diagram showing an upper surface of a piezoelectric element;

FIGS. 8A and 8B are cross-sectional views of the piezoelectric element;

FIG. 9 is a diagram showing an upper surface of a piezoelectric element;

FIG. 10 is a cross-sectional view taken along line X-X in FIG. 9;

FIG. 11 is a diagram showing an upper surface of a piezoelectric element;

FIG. 12 is a cross-sectional view of a piezoelectric element;

FIG. 13 is a diagram showing an upper surface of a piezoelectric element;

FIG. 14 is a cross-sectional view taken along line XIV-XIV in FIG. 13; and

FIG. 15 is a cross-sectional view taken along line XV-XV in FIG. 13.

FIG. 16 is a diagram showing a liquid ejection head.

### DESCRIPTION OF THE EMBODIMENTS

### First Embodiment

A first embodiment of the present disclosure will be described below with reference to the drawings.

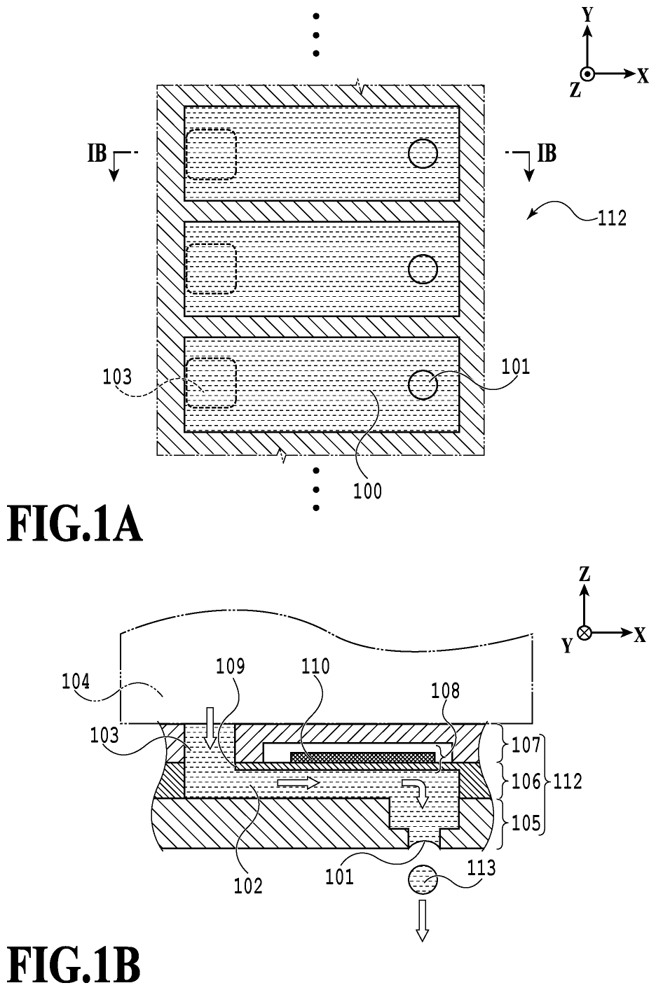

FIGS. 1A and 1B are diagrams showing an element substrate 112 formed by combining a first channel substrate 105, a second channel substrate 106, and a third channel substrate 107. If a general-purpose MEMS process is employed, silicon substrates are generally used for the three types of substrates, the first channel substrate 105, the second channel substrate 106, and the third channel substrate 107. Other members, such as a mold, may be used in combination with the silicon substrates. In the following drawings, an X direction indicates a direction in which nozzle arrays 200 to be described later are arranged, a Y direction indicates a direction in which ejection ports 101 to be described later are arranged, and a −Z direction indicates a direction in which ink is ejected.

A plurality of channel blocks 100 are formed in the element substrate 112. FIG. 1A is a perspective view seen from a surface including the ejection ports 101 of the plurality of channel blocks 100. FIG. 1B is a cross-sectional view taken along line IB-IB in FIG. 1A. As shown in FIGS. 1A and 1B, the channel blocks 100 each include the ejection port 101, and a pressure chamber 102 and a supply channel 103, which are connected to each of the ejection ports 101. Each of the supply channels connected to a common liquid chamber 104 supplies ink to the pressure chamber 102. The arrows shown in FIG. 1B indicate the ink flow.

As shown in FIG. 1B, the element substrate 112 is formed by laminating in the Z direction the first channel substrate 105 including the ejection port 101, the second channel substrate 106 having a piezoelectric element 108 and the pressure chamber 102, and the third channel substrate 107 including an ink supply channel that isolates the piezoelectric element 108 from the ink. The supply channel 103, the pressure chamber 102, and the ejection port 101 are formed corresponding to each piezoelectric element 108. The pressure chamber 102 is separated from the adjacent pressure chamber 102 in the Y direction by a partition, and each pressure chamber is not directly affected by the adjacent piezoelectric element 108.

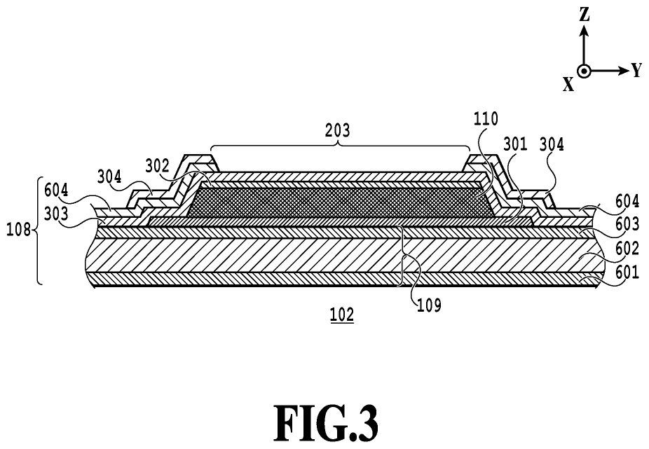

Here, the piezoelectric element 108 is formed by laminating a vibration plate 109, a piezoelectric film 110, a first electrode 301, a second electrode 302, a first insulating film 303, a second insulating film 604, and a protective film 304, which will be described later with reference to FIG. 3. The vibration plate 109 generates pressure on the liquid in the pressure chamber by the action of the piezoelectric film 110. That is, the ink contained in the pressure chamber 102 forms a meniscus at the ejection port 101 in a stable state. In a case where a voltage is applied to the piezoelectric element 108 according to an ejection signal, the piezoelectric element 108 is flexuously deformed to expand or contract the volume of the pressure chamber 102. By combining the expansion and contraction operations, an ink droplet 113 is generated from the meniscus and ejected to the outside air side (−Z direction). The pressure is thus applied to the liquid in the pressure chamber by the action of the piezoelectric element 108 and the vibration plate 109. The ink in the pressure chamber 102 consumed by the ejection operation is supplied from the common liquid chamber 104 by capillary force, and the meniscus is reformed at the ejection port 101. In the present embodiment, the combination of the ejection port 101, the piezoelectric element 108, and the pressure chamber 102 is referred to as an ejection element.

The vibration plate 109 can be made of a silicon nitride film, silicon, metal, heat-resistant glass or the like, depending on required mechanical properties and reliability. The piezoelectric film 110 can be formed by vacuum sputtering, sol-gel solution, chemical vapor deposition (CVD) or the like. Many piezoelectric films 110 are calcined after formation, and the calcination is performed, for example, at a maximum of 600 to 800° C. in an oxygen atmosphere by lamp annealing or the like. The film may be formed directly on the vibration plate 109 and integrally calcined, or may be formed on a separate substrate and calcined before being peeled and transferred to the vibration plate 109 side, or may be formed on a separate substrate and peeled and transferred to the vibration plate 109 side before being integrally calcined.

Referring again to FIG. 3, the first electrode 301 is formed on one surface of the piezoelectric film 110, and the second electrode 302 is formed on the other surface of the piezoelectric film 110. As for the first electrode 301 and the second electrode 302, a precious metal, such as Pt and Ir, with high heat resistance is selected in a case of going through a calcination process. In a case where the calcination process can be separated, on the other hand, Au-based alloy, Al-based alloy, or the like can also be selected. PZT-based ceramics are widely known as the piezoelectric film 110. From the viewpoint of controllability, it is desirable to use a material with high linearity in terms of voltage response displacement and to drive within a voltage range with high linearity. However, in reality, saturation characteristics, hysteresis characteristics, nonlinearity of electrostriction and the like affect the displacement characteristics.

In the present embodiment, the individual ejection elements (hereinafter also referred to as nozzles) may be arranged in the Y direction at a density of 150 npi (nozzle per inch), or may be arranged at a higher density of, for example, 300 npi or 600 npi. The viscosity of the ink used is about several to a dozen cP, and the drive waveform is adjusted so that the minimum ink ejection amount from each ejection port 101 is several pL. In a case where the nozzle density is 300 npi, the width of the liquid chamber is narrower than that in a case where the nozzle density is 150 npi. Therefore, the vibration plate 109 is designed to be thin to ensure necessary amount of displacement. Furthermore, each piezoelectric element 108 is often designed to have a drive frequency of several tens of kHz. Such a drive frequency is set from the time required for each ejection element to actually eject ink after a voltage is applied to the piezoelectric element 108, and then to refill with new ink for the next ejection operation.

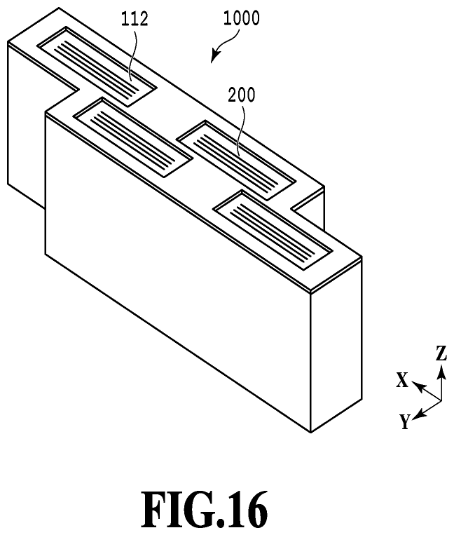

As shown in FIG. 16, a liquid ejection head 1000 is often configured as one head by arranging a plurality of element substrates 112, each of which is one unit (one chip) including a plurality of ejection elements arranged therein. Each element substrate 112 is generally connected to a flexible printed circuit board, and further connected to an electric wiring board. A power supply terminal for supplying power to the element substrate 112 and a signal input terminal for receiving an ejection signal are disposed on the electric wiring board.

On the other hand, an ink supply unit may have a circulation channel formed therein that supplies ink containing a color material supplied from an ink tank to each element substrate 112 and collects ink not consumed in printing.

With the above configuration, each ejection element arranged on the element substrate 112 uses power supplied from the power supply terminal to eject ink supplied by the ink supply unit from the ejection port 101 to the outside air side (−Z side) based on printing data inputted from the signal input terminal. Note that the dimensional values of each part described above are merely an example and may be changed as appropriate depending on the specifications.

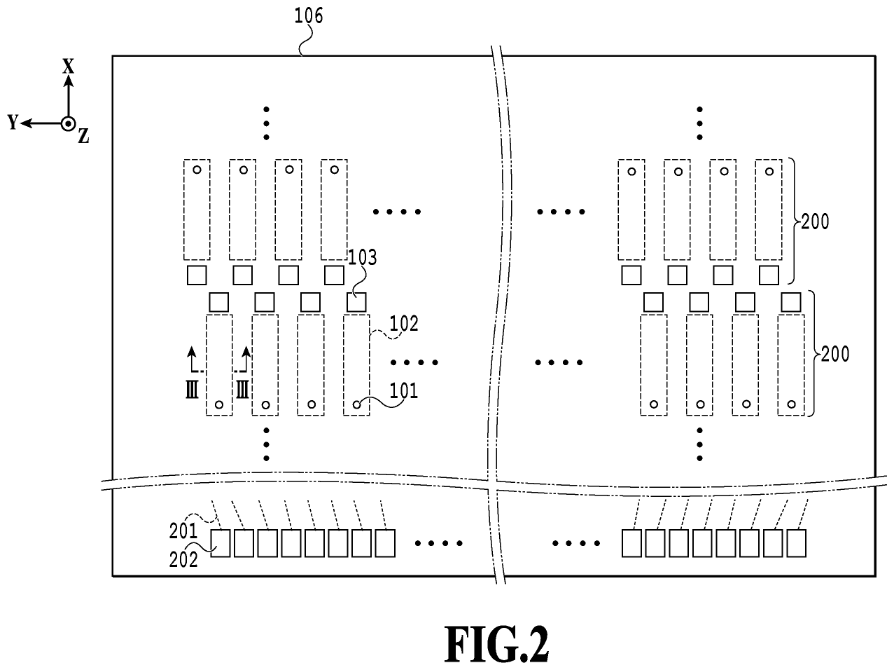

FIG. 2 is a top view of the second channel substrate 106 of the element substrate 112 as seen from the piezoelectric film 110 side. The piezoelectric film 110 (see FIG. 3 to be described later) and the pressure chamber 102 are formed in the second channel substrate 106. For the formation, a MEMS process using a silicon substrate is preferably employed. On the element substrate 112, a plurality of nozzle arrays 200 are arranged along the +X direction, and nozzles are arranged along the +Y direction with a specified density and a specified nozzle length. At least two nozzle arrays 200 are arranged, and up to eight arrays or the like may be employed. The length of the nozzle array is generally selected from a range of about 0.5 inches to up to about 1.5 inches. One liquid ejection head is configured by combining a plurality of such element substrates 112.

On the second channel substrate 106 constituting the element substrate 112 shown in FIG. 2, a wiring 201 is disposed to supply corresponding electric signals to the first electrode 301 (see FIG. 3 to be described later) and the second electrode 302 (see FIG. 3 to be described later) of each piezoelectric film 110. The second channel substrate 106 is provided with pad portions 202 for electrical connection with an external electric substrate. The shape of the pad portions 202 is appropriately designed according to the mounting method. The pad portions 202 may be arranged only on one side of the second channel substrate 106 as shown in FIG. 2, or may be arranged separately on both sides. The advantage of arranging the pad portions 202 only on one side of the second channel substrate 106 is reduced number of mounting members and steps. Using a flexible cable with an IC mounted as a mounting member enhances the effect of reducing material costs. However, in a case where the wiring is concentrated on one side, the wiring density in the wiring routing area increases, leading to stricter arrangement constraints that requires optimized wiring arrangement. Furthermore, the wiring may be distributed to each layer by making the wiring into a laminated structure, and the planar arrangement space constraints may be avoided.

The liquid chamber width becomes narrower as the nozzle density increases. Therefore, a large displacement is required for the piezoelectric element 108 to eject a predetermined amount of ink, and the curvature of the vibration plate needs to be increased. A large curvature during deformation increases stress at the end portion of the piezoelectric element 108, leading to a possibility that peeling may occur. Therefore, there is a method of forming a protective film to prevent peeling, but if the protective film is wide or thick, there is a possibility that peeling may occur due to stress concentration caused by residual stress in the film, or a possibility of impeding the displacement of the piezoelectric element 108. Therefore, in the present embodiment, a part of the upper surface and the side surface portion of the piezoelectric element 108 are covered with a protective film.

With reference to the accompanying drawings, description will be given below of the piezoelectric element 108 as a microstructure formed using a semiconductor process according to the present embodiment. Note that the present embodiment will be described with a focus on the configuration and manufacturing method of the piezoelectric element 108.

Note that the components described in the following embodiments are merely examples, and are not intended to limit the scope of the present disclosure to these alone. The present disclosure will be described using an example of employing a liquid ejection method, but is not limited thereto, and various modifications and changes are possible within the scope of the gist.

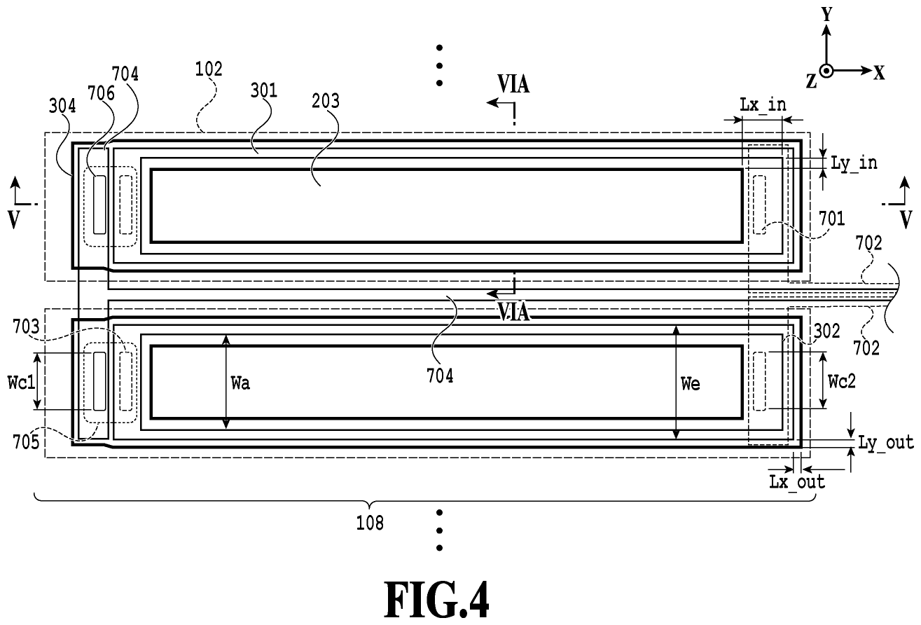

In the present embodiment, the individual ejection elements (nozzles), that is, the piezoelectric elements 108, are arranged at a density of 300 npi in the Y direction. With reference to FIG. 4, the size of the piezoelectric element 108 is 700 μm (length) in the X direction and 50 μm (width) in the Y direction. The size of the pressure chamber 102 is 750 μm (length) in the X direction, 55 μm (width) in the Y direction, and 100 μm (height) in the Z direction. Since the width of the liquid chamber is narrower than that in the case of 150 npi, the amount of displacement required is ensured by designing the vibration plate 109 to be thin. Referring again to FIG. 2, the diameter of the ejection port 101 is 20 μm. The nozzle diameter, which is the diameter of the ejection port 101, is a value that is adjusted according to the specifications of the ejected droplets, and can be selected from a range of about 10 to 30 μm.

FIG. 3 is a schematic cross-sectional view taken along line III-III in FIG. 2. The piezoelectric element 108 will be described with reference to FIG. 3. A membrane-like piezoelectric element 108 is formed at a position corresponding to the pressure chamber 102. The piezoelectric element 108 is formed by laminating the vibration plate 109, the first electrode 301, the piezoelectric film 110, the second electrode 302, the first insulating film 303, the second insulating film 604, and the protective film 304 in this order from the pressure chamber 102 side. The protective film 304 has an opening in a region 203 above the piezoelectric film 110.

In a case of using an oxide-based ceramic as the piezoelectric film 110, it may be preferable to form a reduction inhibition film on the piezoelectric film 110 before forming the insulating films. Although SiO-based films are often used in a CVD apparatus as a general insulating film, the oxide on the film formation side may be easily reduced during gas reaction. Once reduced, the interface of Schottky junction between the piezoelectric film 110 and the second electrode 302 collapses, causing deterioration in leakage characteristics of the piezoelectric film 110, which may lead to degradation of long-term reliability. To prevent this, it is effective to form an oxide film (not shown) such as Al₂O₃ using an ALD apparatus as one of the reduction inhibition films.

An SiO-based or SiN-based film is then formed as the first insulating film 303 of the wiring using CVD8 or TEOS (Tetra Eth Oxy Silane). Thereafter, an electrical contact with the piezoelectric film 110 is formed in the first insulating film 303. In the next step of forming a wiring, an Al-based alloy film is often mainly used, but other alloy films may also be used. Then, an SiO-based or SiN-based film is formed as a sealing film (not shown) using CVD or TEOS. Finally, the sealing film is removed from the connection area of the pad portion 202 shown in FIG. 2.

The piezoelectric element 108 in the liquid ejection head according to the present embodiment is for flexuous deformation. Therefore, an increase in thickness of the films above the piezoelectric film 110 makes it less likely for flexuous deformation to occur, leading to a possibility that a desired effect may not be achieved. To efficiently achieve flexuous deformation, it is preferable that a neutral plane defined by material mechanics is positioned near the interface between the piezoelectric film 110 and the vibration plate 109, preferably slightly toward the vibration plate 109. With the first insulating film 303 additionally formed above the piezoelectric film 110, the neutral plane shifts to the inside of the piezoelectric film 110, making it difficult to bend. Such bending is also suppressed in a case where the protective film 304 is formed on the surface side of the piezoelectric film 110. It is preferable to form a necessary film thickness in parts where insulation and sealing functions are required, such as electrical contact, and to partially remove or thin the films above the piezoelectric film 110 so that a minimum film thickness required for sealing remains. This makes it possible to improve displacement efficiency of the flexuous deformation.

The region 203 where the inorganic film on the piezoelectric film 110 is thinned or removed is realized by masking with a photoresist by photolithography processing and a removing step by semiconductor plasma etching.

FIG. 4 is a top view showing the vicinity of III-III in FIG. 2. In the present embodiment, the protective film 304 is formed above the end portion of the first electrode 301, on the end portion of the second electrode 302 above the piezoelectric film 110 (see FIG. 3), and on a second layer wiring 704 above a contact portion 706. As shown in FIG. 4, as seen from the direction perpendicular to the substrate, the protective film 304 continuously covers a region overlapping the periphery of the piezoelectric film 110. The protective film 304 has an opening in the region 203 that is a part of the region of the second electrode 302 on the piezoelectric film 110. The region of the pressure chamber 102 without the protective film 304 is wider than the region with the protective film 304.

Inside the pressure chamber 102 region, the protective film 304 protrudes from the end portion of the second electrode 302 on the piezoelectric film 110. Lx_in is the protruding amount in the X direction and Ly_in is the protruding amount in the Y direction. The protective film 304 also protrudes from the end portion of the first electrode 301. Lx_out is the protruding amount in the X direction and Ly_out is the protruding amount in the Y direction. Wc1 is the width of the contact portion 703 in the Y direction (width direction), Wa is the width of the second electrode 302 in the Y direction, We is the width of the first electrode 301 in the Y direction, and Wc2 is the width of the contact portion 701 in the Y direction.

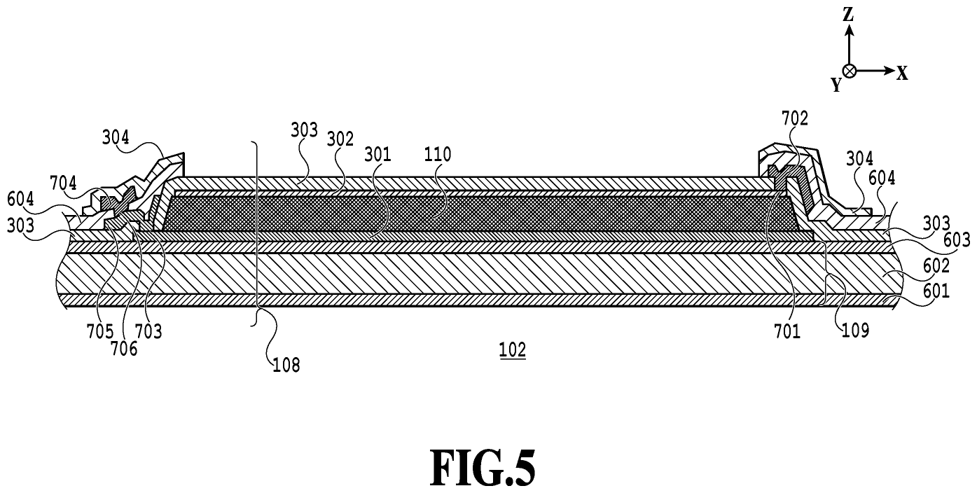

FIG. 5 is a cross-sectional view taken along line V-V in FIG. 4. A membrane-like piezoelectric element 108 is formed at a position corresponding to the pressure chamber 102 (on the surface of the vibration plate 109 opposite to the pressure chamber 102). The piezoelectric element 108 is formed by laminating the vibration plate 109, the first electrode 301, the piezoelectric film 110, the second electrode 302, the first insulating film 303, the first layer wiring 702 and a relay portion 705, the second insulating film 604, the second layer wiring 704, and the protective film 304 in this order from the pressure chamber 102 side. The first insulating film 303 insulates the relay portion 705 from the first electrode 301 in a region other than the contact portion 703. The second insulating film 604 insulates the relay portion 705 from the second layer wiring 704 in a region other than the contact portion 706.

The relay portion 705 bridges the first electrode 301 and the second layer wiring 704. The second electrode 302 and the first layer wiring 702 are electrically connected at the contact portion 701. The contact portion 703 electrically connects the first electrode 301 and the relay portion 705. The first layer wiring 702 and the second layer wiring 704 are thus electrically connected through the piezoelectric film 110.

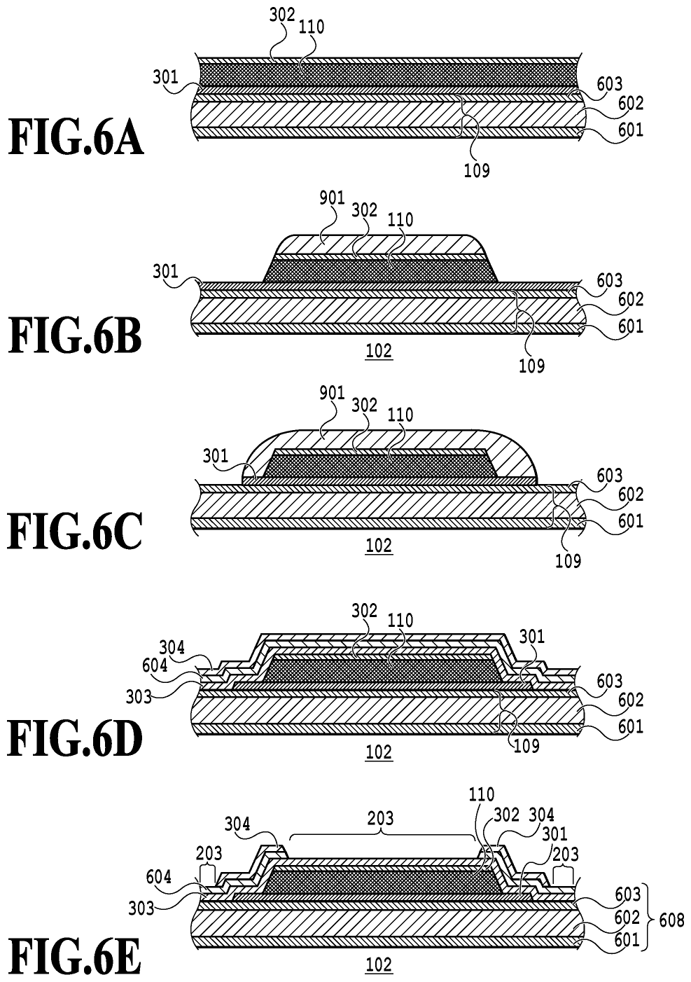

FIGS. 6A to 6E are diagrams sequentially showing steps of manufacturing the piezoelectric element 108. The steps of manufacturing the piezoelectric element 108 will be described below. First, as shown in FIG. 6A, an SOI (silicon on insulator) substrate is prepared as the vibration plate 109, with a buried oxide (BOX) layer 601 having a thickness of 0.5 to 1.0 μm and a device layer 602 having a thickness of 0.75 to 1.25 μm. Then, a 250 nm thick oxide film 603 is formed on the surface of the SOI substrate by thermally oxidizing the device layer. A Pt/TiO₂/Ti laminate film is then formed thereon as the first electrode 301 of the piezoelectric element 108. A PZT film having a thickness of 1.5 to 2.5 μm is formed as the piezoelectric film 110 by a sol-gel method, and a Ti-based alloy film is formed as the second electrode 302.

Next, as shown in FIG. 6B, the second electrode 302 and the PZT film are patterned by photolithography (resist pattern 901) and etched. This forms a pattern of the piezoelectric film 110 and the second electrode 302 at a position corresponding to the pressure chamber 102 formed in a channel formation step. The size of the piezoelectric film 110 is 45 to 50 μm in the width direction and 500 to 650 μm in the longitudinal direction. The photoresist is then removed before proceeding to the next step.

As shown in FIG. 6C, a pattern of the first electrode 301 is formed by photolithography (resist pattern 902) so as to have a width of several μm to 10 μm from the PZT region and then etching. The photoresist is then removed before proceeding to the next step.

As shown in FIG. 6D, an Al₂O₃ film having a thickness of about 20 nm is formed as a barrier film (not shown) to prevent damage to the PZT film during the process. Then, a TEOS oxide film having a thickness of 400 nm is formed as the first insulating film 303 to prevent leakage between elements. Next, electrical contact portions shown in FIGS. 4 and 5 are formed. A contact portion 701 (see FIGS. 4 and 5) for electrically connecting the second electrode 302 of the piezoelectric film 110 to the wiring is formed, and then a contact portion 703 (see FIGS. 4 and 5) for electrically connecting the first electrode 301 of the piezoelectric film 110 to the wiring is formed. Thereafter, an AlCu alloy film is formed, and a relay portion 705 (see FIGS. 4 and 5) for bridging the first layer wiring 702 (see FIGS. 4 and 5) and the second layer wiring 704 (see FIGS. 4 and 5) with the first electrode 301 is simultaneously formed through a series of semiconductor processes. Next, a TEOS oxide film having a thickness of 400 nm is formed as the second insulating film 604 to prevent leakage between the wirings, and a contact portion 706 (see FIGS. 4 and 5) is formed on the region of the relay portion 705 to be electrically connected to the first electrode 301.

Here, since the electrical pad portions 202 (see FIG. 2) are to be located above the second insulating film 604 (below the protective film 304), the wiring 702 located in the first layer (lower layer) needs to be connected to the second layer (upper layer). To this end, an opening (not shown) for pad connection is formed in the second insulating film 604 near the pad portion 202. Thereafter, an AlCu alloy film that constitutes the second layer wiring is formed, and the wiring 704 located in the second layer is formed through a series of semiconductor processes. Then, the second layer wiring 704 is formed, which is electrically connected to the first electrode 301 through the relay portion 705. At the same time, the first layer wiring 702 electrically connected to the second electrode 302 is electrically connected to the pad portion 202. The wiring located in the second layer is thus formed.

The wiring 201 (see FIG. 2) corresponding to the first electrode 301 and the second electrode 302 is thus electrically connected to the pad portion 202. A configuration with a multi-layered wiring is thus realized. An SiN-based protective film 304 is formed having a thickness of about 200 nm on the uppermost surface layer (surface) (protective film formation). The protective film 304 is made of an inorganic material, and may be a film containing at least SiO or any of Al, Zr, and Hf.

Furthermore, the film thickness of the protective film 304×Young's modulus E is 10 to 80% of the film thickness of the piezoelectric film 110×Young's modulus Ep, where Young's modulus E is the Young's modulus of each material of the protective film 304 and Young's modulus Ep is the Young's modulus of the piezoelectric film 110. It is preferable that residual stress of the protective film 304 is within +100 MPa (weak compression to weak tension).

As shown in FIG. 6E, the second insulating film 604 and the protective film 304 above the piezoelectric film 110 are removed, and the protective film 304 around the piezoelectric element 108 is removed to form the region 203 where the protective film 304 has been removed. Finally, the upper inorganic film of the pad portion 202 is removed to expose the metal surface. Through these steps, the piezoelectric element 108 is completed.

Here, in FIG. 4, inside the pressure chamber 102, the protective film 304 invades the second electrode 302 from the end portion of the second electrode 302 above the piezoelectric film 110. It is preferable that the protruding amounts Lx_in and Ly_in in the X and Y directions are both 5 to 10 μm. More specifically, the protective film 304 covers up to the portion where it invades inward by more than or equal to 5 μm and less than or equal to 10 μm from the end portion of the second electrode 302. The protective film 304 also protrudes from the end portion of the first electrode 301. It is preferable that the protruding amounts Lx_out and Ly_out in the X and Y directions are both more than or equal to 5 μm and less than or equal to 10 μm.

It is also preferable that the width Wc1 of the contact portion 703 is more than or equal to 70% and less than or equal to 100% of the width We of the first electrode 301 below the piezoelectric film 110. In other words, it is preferable that the following relationship is satisfied.

$$We \times 0.7 \leq Wc 1 \leq We$$

It is also preferable that the width Wc2 of the contact portion 701 is 70% or more and 100% or less of the width Wa of the second electrode 302. In other words, it is desirable to satisfy the following relationship.

$$Wa \times 0.7 \leq Wc 2 \leq Wa$$

The preferable conditions described above are conditions for preventing peeling as a result of considering, with a process tolerance, how to suppress peeling while maintaining displacement that satisfies the specifications of ejected droplets.

The protective film 304 is thus formed that covers a part of the region including the end portion of the first electrode 301 below the piezoelectric film 110, a part of the region including the end portion of the second electrode 302 above the piezoelectric film 110, and the second layer wiring 704 above the contact portion 706, across the boundary end of the piezoelectric film 110. This makes it possible to alleviate the residual stress in the protective film, making it less likely for peeling to occur due to stress concentration. This makes it possible to realize a piezoelectric element 108 with high fastness while ensuring necessary displacement amount of the piezoelectric element 108.

### Second Embodiment

A second embodiment of the present disclosure will be described below with reference to the drawings. Note that a basic configuration of the present embodiment is the same as that of the first embodiment, and thus characteristic configurations will be described below.

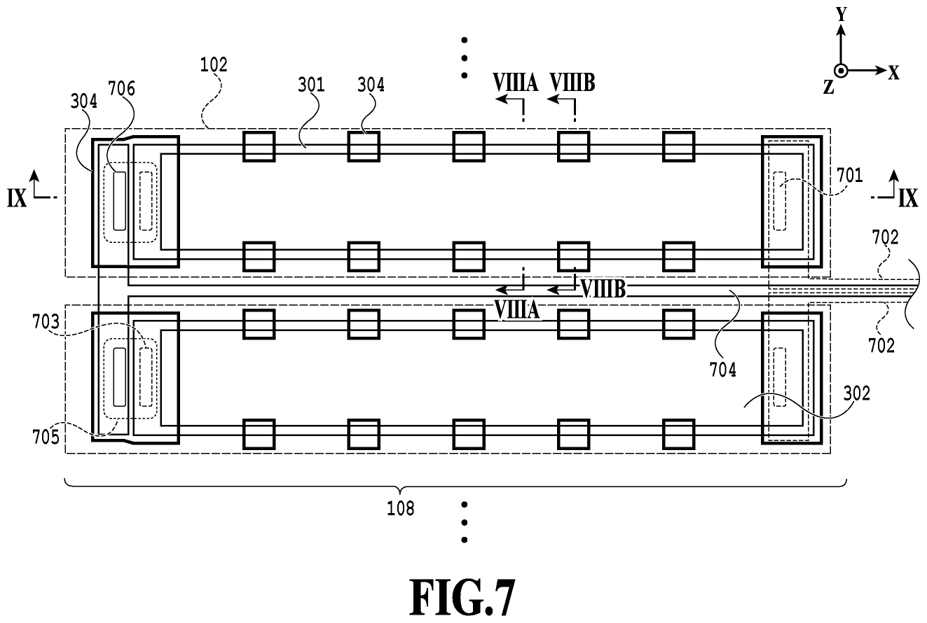

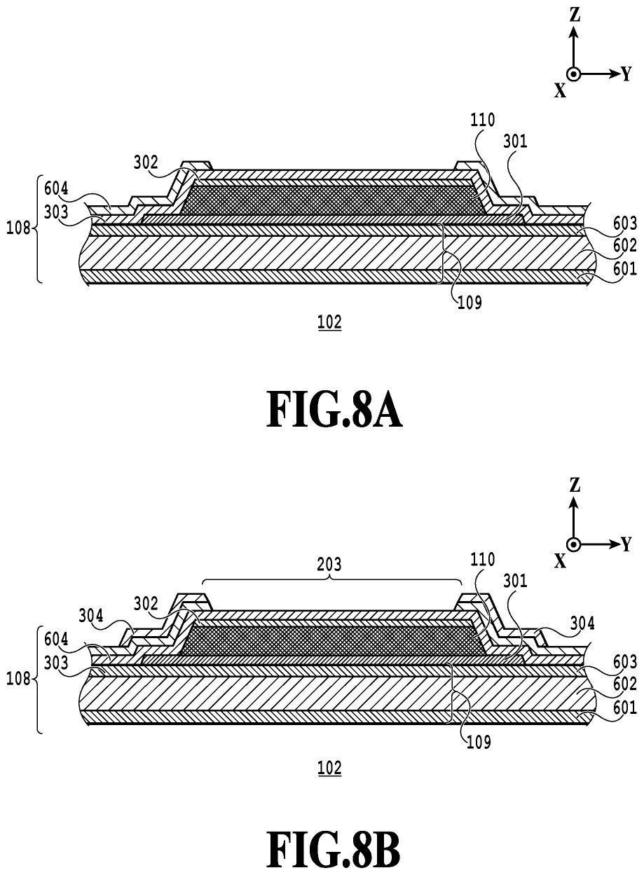

FIG. 7 is a diagram showing an upper surface of the piezoelectric element 108 according to the present embodiment. FIG. 8A is a cross-sectional view taken along line VIIIA-VIIIA in FIG. 7. FIG. 8B is a cross-sectional view taken along line VIIIB-VIIIB in FIG. 7. In the piezoelectric element 108 of the present embodiment, a protective film 304 is formed on both end portions of a first electrode 301 in the X direction below the piezoelectric film 110, on both end portions of a second electrode 302 in the X direction above the piezoelectric film 110, and on a second layer wiring 704 above a contact portion 706. More specifically, the quadrangular protective film 304 is formed so as to partially cover both end portions of the first electrode 301 in the Y direction and both end portions of the second electrode 302 in the Y direction. In the present embodiment, as shown in FIG. 7, the protective film 304 is provided at five locations in both end portions of the first electrode 301 and the second electrode 302 in the Y direction.

As described above, as seen from the direction perpendicular to the substrate, a boundary of a piezoelectric film 110 between the both end portions is partially covered with a plurality of protective films 304. As a result, deflection is less likely to occur in the protective film 304 at the end portions other than the corners of the piezoelectric film 110 and the electrode upon deformation of the piezoelectric element 108, making it possible to prevent peeling due to deflection in the protective film 304.

### Third Embodiment

A third embodiment of the present disclosure will be described below with reference to the drawings. Note that a basic configuration of the present embodiment is the same as that of the first embodiment, and thus characteristic configurations will be described below.

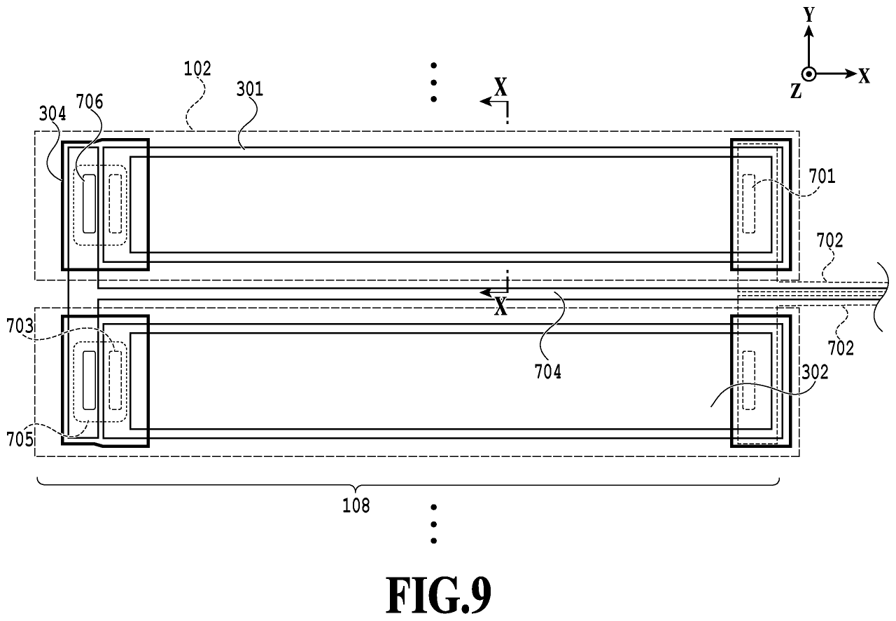

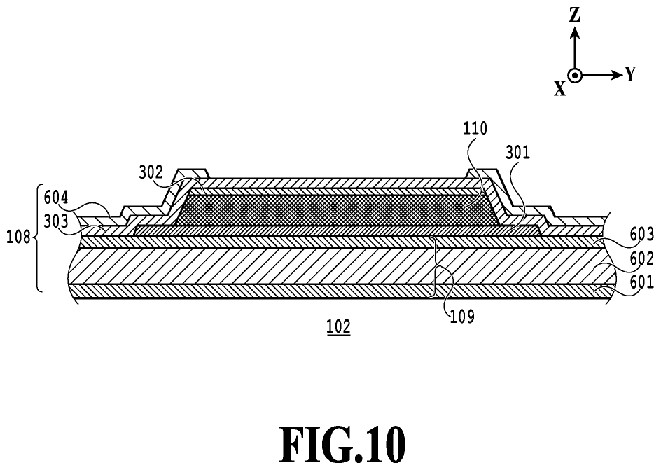

FIG. 9 is a diagram showing an upper surface of a piezoelectric element 108 according to the present embodiment. FIG. 10 is a cross-sectional view taken along line X-X in FIG. 9. In the piezoelectric element 108 of the present embodiment, a protective film 304 is formed on both end portions of a first electrode 301 in the X direction below the piezoelectric film 110 and on both end portions of a second electrode 302 in the X direction above the piezoelectric film 110, as in the second embodiment. More specifically, the protective film 304 is divided and formed on one end side and the other end side of the piezoelectric film 110 in the longitudinal direction of the piezoelectric film 110. Furthermore, as in the second embodiment, the protective film 304 is formed on a second layer wiring 704 above a contact portion 706. The present embodiment is also different from the second embodiment in that the protective film 304 is not formed on both end portions of the first electrode 301 in the Y direction and both end portions of the second electrode 302 in the Y direction, except for the portions covered by both end portions in the X direction.

In the present embodiment, a membrane-like piezoelectric element 108 is formed at a position corresponding to the pressure chamber 102. In the center of the pressure chamber 102 (center in the X direction), as shown in FIG. 10, a vibration plate 109, the first electrode 301, the piezoelectric film 110, the second electrode 302, a first insulating film 303, and a second insulating film 604 are laminated in this order from the pressure chamber 102 side, and the protective film 304 is removed. The protective film 304 thus formed can intensively suppress peeling of the piezoelectric film 110 and the corners of the electrode.

### Fourth Embodiment

A fourth embodiment of the present disclosure will be described below with reference to the drawings. Note that a basic configuration of the present embodiment is the same as that of the first embodiment, and thus characteristic configurations will be described below.

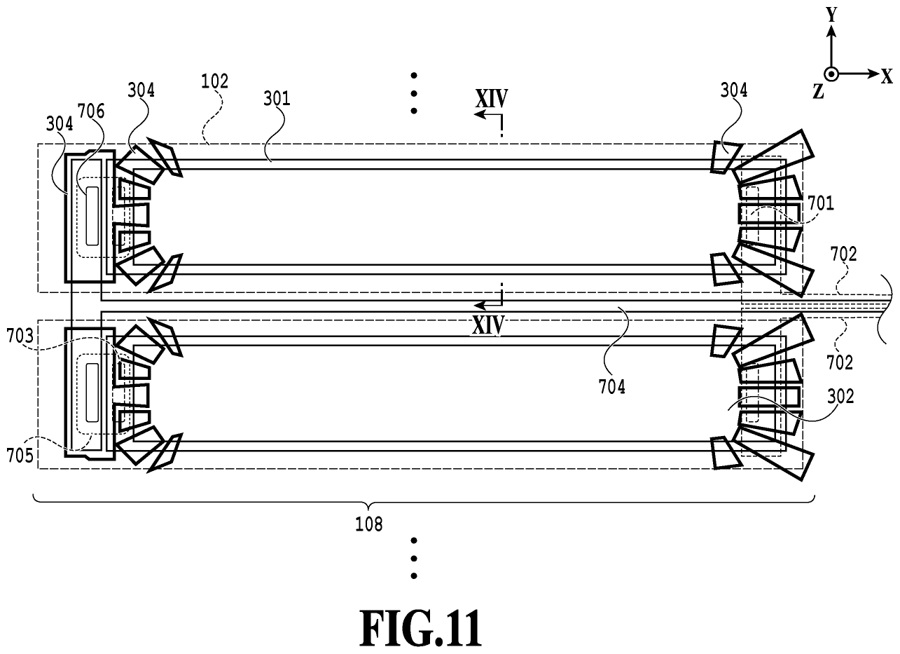

FIG. 11 is a diagram showing an upper surface of a piezoelectric element 108 according to the present embodiment. In the piezoelectric element 108 of the present embodiment, a protective film 304 is formed so as to cover an end portion of a first electrode 301 in the −X direction and a second layer wiring 704 above a contact portion 706 (in the Z direction). In the piezoelectric element 108, the protective film 304 is also formed radially outward at an end portion of the first electrode 301 in the X direction and both end portions of the second electrode 302 in the X direction.

More specifically, the protective film 304 extending in the YX direction, X direction, and −YX direction is partially provided at the end portion of the first electrode 301 in the X direction, thereby forming a radial protective film 304. Moreover, the protective film 304 extending in the −XY direction, −X direction, and −X-Y direction is partially provided at the end portion of the first electrode 301 in the −X direction, thereby forming a radial protective film 304. Furthermore, the protective film 304 extending in the −XY direction, −X direction, and −X-Y direction is partially provided at the end portion of the second electrode 302 in the −X direction, thereby forming a radial protective film 304. The protective film 304 extending in the YX direction, X direction, and −YX direction is partially provided at the end portion of the second electrode 302 in the X direction, thereby forming a radial protective film 304. In the protective film 304 radial toward the outside of the piezoelectric element 108, the size (area) of the protective film 304 disposed at the corners of the first electrode 301 and the second electrode 302 is larger than the size (area) of the protective film 304 disposed in the other locations.

By forming such a radial protective film 304, wrinkles are less likely to occur in the protective film 304 near the corners of the piezoelectric film 110 and the electrodes upon deformation of the piezoelectric element 108, making it possible to suppress peeling due to wrinkles.

### Fifth Embodiment

A fifth embodiment of the present disclosure will be described below with reference to the drawings. Note that a basic configuration of the present embodiment is the same as that of the first embodiment, and thus characteristic configurations will be described below.

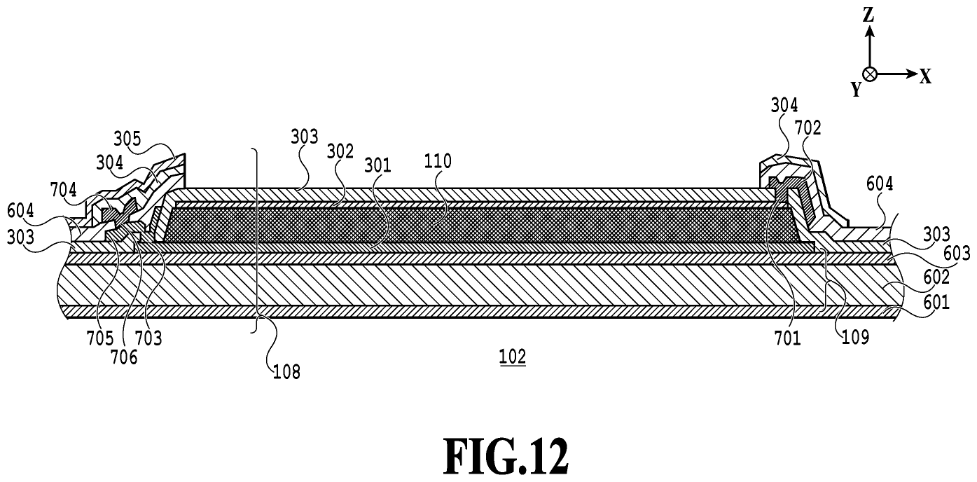

FIG. 12 is a cross-sectional view of a piezoelectric element 108 according to the present embodiment. In the piezoelectric element 108 of the present embodiment, an Al₂O₃ film (not shown) is formed having a thickness of about 20 nm on a protective film 304, and a protective film 305 is formed thereon having a thickness of about 200 nm. The protective film 305 is then etched using photolithography to leave only the protective film 305 on the contact portion 703 side.

By thus forming the protective film 305 on the contact portion 703 side, the protective film on the contact portion 703 side is made thicker. This makes it possible to set substantially the same height of the protective film on the contact portion 701 side and the contact portion 703 side. As a result, the bias in stress on the entire piezoelectric element 108 can be reduced and the occurrence of peeling can be suppressed.

### Sixth Embodiment

A sixth embodiment of the present disclosure will be described below with reference to the drawings. Note that a basic configuration of the present embodiment is the same as that of the first embodiment, and thus characteristic configurations will be described below.

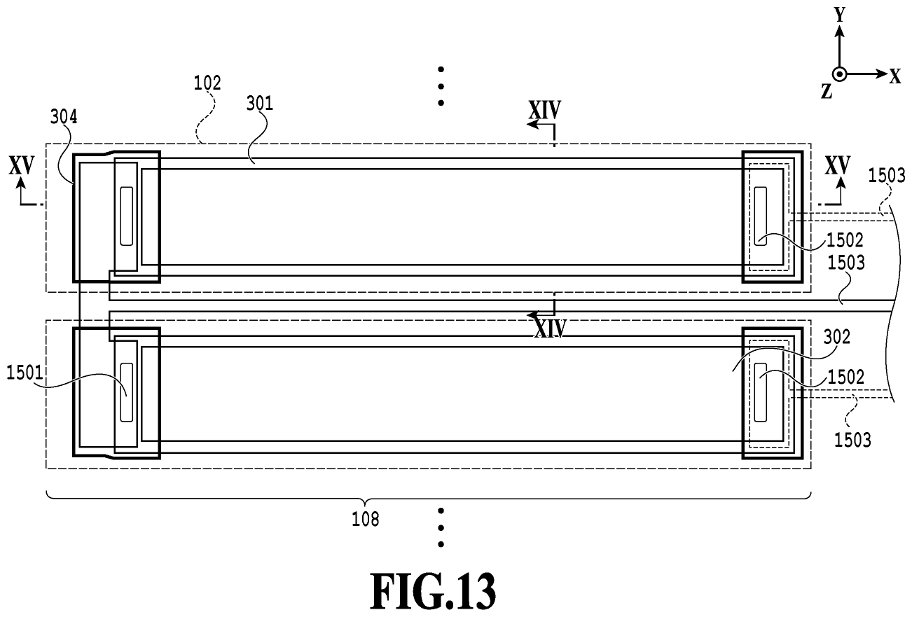

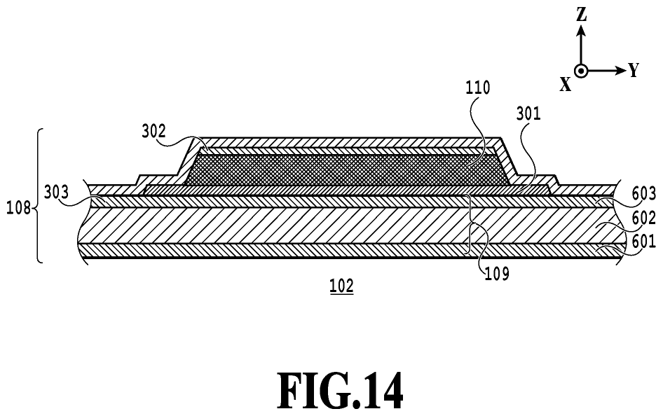

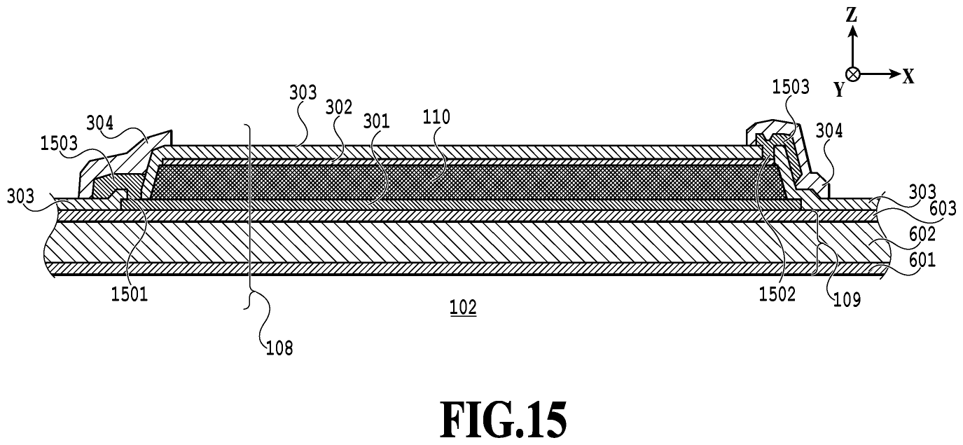

FIG. 13 is a diagram showing an upper surface of a piezoelectric element 108 according to the present embodiment. FIG. 14 is a cross-sectional view taken along line XIV-XIV in FIG. 13. FIG. 15 is a cross-sectional view taken along line XV-XV in FIG. 13. The piezoelectric element 108 of the present embodiment has a wiring structure that differs from the multi-layered wiring configuration of the above embodiments. More specifically, two types of wirings (a wiring for the first electrode 301 and a wiring for the second electrode 302) are located in the same layer. Since the two types of wirings are located in the same layer in the thickness direction, it is sufficient to have a first insulating film 303 that insulates a wiring 1503 from the first electrode 301, and no second insulating film 604 is used.

As shown in FIG. 14, a membrane-like piezoelectric element 108 is formed at a position corresponding to a pressure chamber 102. In the center of the pressure chamber 102 in the X direction, a vibration plate 109, the first electrode 301, the piezoelectric film 110, the second electrode 302, and the first insulating film 303 are laminated in this order from the pressure chamber 102 side, and the protective film 304 is removed. As shown in FIG. 15, a protective film 304 is formed at the end portion of the piezoelectric element 108.

As shown in FIG. 15, in the piezoelectric element 108 of the present embodiment, a TEOS oxide film as the first insulating film 303 and a SiN film as the protective film 304 are formed above the piezoelectric film 110. In the piezoelectric element 108, a contact portion 1501 between the first electrode 301 and the wiring 1503 and a contact portion 1502 between the second electrode 302 and the wiring 1503 are formed, and the wiring 1503 is formed on the first insulating film 303.

In each of the above embodiments, the individual piezoelectric elements are arranged in the Y direction at a density of 150 npi (nozzle per inch). The size of the piezoelectric element 108 is 500 μm in length in the X direction and 110 μm in width in the Y direction. The ejection port 101 (see FIG. 1) has a diameter of 25 μm and a thickness of 30 μm. The first channel substrate 105 has a thickness of 100 μm. The size of the pressure chamber 102 is 550 μm in length in the X direction, 120 μm in width in the Y direction, and 100 μm in height in the Z direction.

By thus forming the protective film 304, even in a wiring configuration in which two types of wirings are located in the same layer, peeling due to stress concentration is less likely to occur, making it possible to suppress peeling from the end portions of the piezoelectric film 110 and the electrodes and peeling in the wiring above the contact portion between the electrode layer and the wiring.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2023-187840 filed Nov. 1, 2023, which is hereby incorporated by reference wherein in its entirety.

What is claimed is:

1. A liquid ejection head comprising:
a laminate of
a substrate having a pressure chamber formed therein that communicates with an ejection port for ejecting a liquid,
a vibration plate that vibrates to generate pressure in the liquid in the pressure chamber,
a piezoelectric film that vibrates the vibration plate by applying a voltage to the piezoelectric film,
a first electrode provided on one surface of the piezoelectric film between the piezoelectric film and the vibration plate, and
a second electrode provided on the other surface of the piezoelectric film;
a first wiring connected to the first electrode by a first contact portion;
a second wiring connected to the second electrode by a second contact portion; and
a protective film having at least a first portion covering a partial region including an end portion of the first electrode, the first contact portion, and the first wiring, and a second portion covering a partial region including an end portion of the second electrode, the second contact portion, and the second wiring, at one end side and the other end side of the piezoelectric film in a longitudinal direction of the piezoelectric film within a range overlapping with the pressure chamber as seen from a direction perpendicular to the substrate.

2. The liquid ejection head according to claim 1, wherein
as seen from the direction perpendicular to the substrate, a region without the protective film is larger than a region with the protective film in a region of the substrate overlapping with the pressure chamber.

3. The liquid ejection head according to claim 1, wherein
as seen from the direction perpendicular to the substrate, the protective film continuously covers a region overlapping a periphery of the piezoelectric film.

4. The liquid ejection head according to claim 1, wherein
the protective film covers both end portions of the piezoelectric film, where the first contact portion and the second contact portion are provided.

5. The liquid ejection head according to claim 1, wherein
the first wiring is connected to the first electrode through a relay portion.

6. The liquid ejection head according to claim 5, wherein
the first electrode is connected to the relay portion through the first contact portion, and the relay portion is connected to the first wiring through a third contact portion.

7. The liquid ejection head according to claim 6, further comprising:
a first insulating film that insulates the relay portion from the first electrode, except for the first contact portion; and
a second insulating film that insulates the relay portion from the first wiring, except for the third contact portion.

8. The liquid ejection head according to claim 4, wherein
as seen from the direction perpendicular to the substrate, a boundary of the piezoelectric film between the both end portions is partially covered with a plurality of the protective films.

9. The liquid ejection head according to claim 4, wherein
the both end portions are partially covered with a plurality of the protective films, and the protective films are provided radially outward from the region of the piezoelectric film.

10. The liquid ejection head according to claim 9, wherein
as seen from a direction perpendicular to the substrate, an area of the protective film disposed at a corner of the first electrode and the second electrode is larger than an area of the protective film disposed at other locations.

11. The liquid ejection head according to claim 4, wherein
a thickness of the protective film covering the end portion of the piezoelectric film where the first contact portion is provided is larger than a thickness of the protective film covering the end portion of the piezoelectric film where the second contact portion is provided.

12. The liquid ejection head according to claim 3, wherein
as seen from the direction perpendicular to the substrate, a length of the protective film protruding outward from the end portion of the first electrode is more than or equal to 5 μm and less than or equal to 10 μm.

13. The liquid ejection head according to claim 12, wherein
as seen from the direction perpendicular to the substrate, the protective film covers up to a portion where the protective film invades the second electrode inward from the end portion of the second electrode by more than or equal to 5 μm and less than or equal to 10 μm.

14. The liquid ejection head according to claim 1, wherein
as seen from the direction perpendicular to the substrate, a relationship We×0.7≤Wc1≤We is satisfied, where Wc1 is a width of the first contact portion in a width direction of the piezoelectric film and We is a width of the piezoelectric film in the width direction.

15. The liquid ejection head according to claim 1, wherein
as seen from the direction perpendicular to the substrate, a relationship Wa×0.7≤Wc2≤Wa is satisfied, where Wc2 is a width of the second contact portion in the width direction of the piezoelectric film and Wa is a width of the piezoelectric film in the width direction.

16. The liquid ejection head according to claim 1, wherein
the film thickness of the protective film×Young's modulus E is more than or equal to 10% and less than or equal to 80% of the film thickness of the piezoelectric film×Young's modulus Ep, where Young's modulus E is the Young's modulus of the protective film and Young's modulus Ep is the Young's modulus of the piezoelectric film.

17. The liquid ejection head according to claim 1, wherein
residual stress of the protective film is within +100 MPa.

18. The liquid ejection head according to claim 1, wherein
the protective film is made of an inorganic material and contains at least SiN, SiO or any one of Al, Zr, and Hf.

19. A liquid ejection head comprising:
a laminate of
a substrate having a pressure chamber formed therein that is communicated with an ejection port for ejecting a liquid,
a vibration plate that vibrates to generate pressure in the liquid in the pressure chamber,
a piezoelectric film that vibrates the vibration plate by applying a voltage to the piezoelectric film,
a first electrode provided on one surface of the piezoelectric film between the piezoelectric film and the vibration plate, and
a second electrode provided on the other surface of the piezoelectric film;
a wiring layer connected to the first electrode by a first contact portion and connected to the second electrode by a second contact portion; and
a protective film having at least a first portion covering a partial region including an end portion of the first electrode and the first contact portion and a second portion covering a partial region including an end portion of the second electrode and the second contact portion, at one end side and the other end side of the piezoelectric film in a longitudinal direction of the piezoelectric film within a range overlapping with the pressure chamber as seen from a direction perpendicular to the substrate.

20. A piezoelectric actuator for liquid ejection head comprising:
a laminate of
a substrate having a pressure chamber formed therein that communicates with an ejection port for ejecting a liquid,
a vibration plate that vibrates to generate pressure in the liquid in the pressure chamber,
a piezoelectric film that vibrates the vibration plate by applying a voltage to the piezoelectric film,
a first electrode provided on one surface of the piezoelectric film between the piezoelectric film and the vibration plate, and
a second electrode provided on the other surface of the piezoelectric film;
a first wiring connected to the first electrode by a first contact portion;
a second wiring connected to the second electrode by a second contact portion; and
a protective film having at least a first portion covering a partial region including an end portion of the first electrode, the first contact portion, and the first wiring, and a second portion covering a partial region including an end portion of the second electrode, the second contact portion, and the second wiring, at one end side and the other end side of the piezoelectric film in a longitudinal direction of the piezoelectric film within a range overlapping with the pressure chamber as seen from a direction perpendicular to the substrate.
